(19) United States
(12) Patent Application Publication
(10) Pub. No.: US 2025/0216443 A1
(43) Pub. Date: Jul. 3, 2025

(54) SEMICONDUCTOR DEVICE HANDLING APPARATUS AND SEMICONDUCTOR DEVICE TESTING APPARATUS

(71) Applicant: ADVANTEST Corporation, Tokyo (JP)

(72) Inventor: Aritomo Kikuchi, Tokyo (JP)

(73) Assignee: ADVANTEST Corporation, Tokyo (JP)

(21) Appl. No.: 19/004,834

(22) Filed: Dec. 30, 2024

(30) Foreign Application Priority Data
Dec. 28, 2023 (JP) 2023-223297

(51) Int. Cl. G01R 31/28; H04B 17/10

(52) U.S. Cl. CPC G01R 31/2867; H04B 17/10

(57) ABSTRACT

A semiconductor device handling apparatus handles a device under test (DUT) to bring a terminal disposed on a first surface of the DUT into contact with a contact portion of a tester comprising a tester transmitter. The semiconductor device handling apparatus includes a holder that holds a second surface of the DUT. The holder includes a holder transmitter that transmits a signal between an optical connection portion disposed on the second surface of the DUT and the tester transmitter. The holder transmitter inputs and outputs an optical signal to and from the optical connection portion.

### CROSS-REFERENCE TO RELATED APPLICATIONS

The present application claims priority from Japanese Patent Application No. 2023-223297 filed on Dec. 28, 2023, the entire content of which is incorporated herein by reference.

### TECHNICAL FIELD

In one aspect, the present invention relates to a semiconductor device handling apparatus that handles a semiconductor device to be tested (hereinafter simply referred to as a “DUT” (Device Under Test)) in order to test the DUT including an electronic circuit and an optical circuit, and a semiconductor device testing apparatus that tests the DUT.

### BACKGROUND ART

An electronic component testing apparatus including a tester for testing a DUT, and a handler for pressing the DUT against a socket attached to the tester is known (refer to, for example, Patent Document 1). This electronic component testing apparatus tests electrical characteristics of the DUT by outputting and inputting test signals to and from the DUT, which is electrically connected to the tester via the socket.

### CITATION LIST

### Patent Document

PATENT DOCUMENT 1: JP 2020-122707 A

The above-described electronic component testing apparatus can test only electronic components. Therefore, semiconductor devices with optical circuits in addition to electronic circuits cannot be tested.

### SUMMARY OF THE INVENTION

One or more embodiments of the present invention provide a semiconductor device handling apparatus and a semiconductor device testing apparatus capable of testing a semiconductor device with the electronic and optical circuits.
[1] An aspect 1 of the present invention is semiconductor device handling apparatus that handles a device under test (DUT) to bring a terminal disposed on a first surface of the DUT into contact with a contact portion of a tester, wherein the semiconductor device handling apparatus comprises a holding portion (holder) holding a second surface of the DUT, the holding portion comprises a second transmission portion (holder transmitter) transmitting a signal between an optical connection portion disposed on the second surface of the DUT and a first transmission portion (tester transmitter) of the tester, and the second transmission portion inputs and outputs an optical signal to and from the optical connection portion.
[2] An aspect 2 of the present invention may be the semiconductor device handling apparatus of the aspect 1, wherein the second transmission portion inputs and outputs an optical signal to and from the first transmission portion.
[3] An aspect 3 of the present invention may be the semiconductor device handling apparatus of the aspect 1 or 2, wherein the second transmission portion comprises: a first optical transmission portion receiving a first optical signal from the first transmission portion and emitting a second optical signal to the optical connection portion; and a second optical transmission portion receiving a third optical signal from the optical connection portion and emitting a fourth optical signal to the first transmission portion.
[4] An aspect 4 of the present invention may be the semiconductor device handling apparatus of the aspect 3, wherein the holding portion comprises a main body including an opposing surface that faces the second surface of the DUT, the first optical transmission portion comprises a first incident portion receiving the first optical signal, the second optical transmission portion comprises a first emission portion emitting the fourth optical signal, and the first incident portion and the first emission portion are disposed on the opposing surface so that the first incident portion and the first emission portion face the first transmission portion.
[5] An aspect 5 of the present invention may be the semiconductor device handling apparatus of the aspect 3 or 4, wherein the second optical transmission portion comprises a second incident portion receiving the third optical signal, the first optical transmission portion comprises a second emission portion emitting the second optical signal, and the second incident portion and the second emission portion are disposed on the opposing surface so that the second incident portion and the second emission portion face the optical connection portion.
[6] An aspect 6 of the present invention may be the semiconductor device handling apparatus of any one of the aspects 3 to 5, wherein the first optical transmission portion comprises a first optical transmission path transmitting an optical signal between the first incident portion and the second emission portion, and the second optical transmission portion comprises a first optical transmission path transmitting an optical signal between the second incident portion and the first emission portion.
[7] An aspect 7 of the present invention may be the semiconductor device handling apparatus of any one of the aspects 3 to 6, wherein the first optical transmission portion further comprises: a first incident portion receiving the first optical signal; and a first lens disposed between the first transmission portion and the first incident portion and condensing the first optical signal at the first incident portion.
[8] An aspect 8 of the present invention may be the semiconductor device handling apparatus of any one of the aspects 3 to 7, wherein the second optical transmission portion further comprises: a first emission portion emitting the fourth optical signal; and a second lens disposed between the first transmission portion and the first emission portion and converting the fourth optical signal emitted from the first emission portion into a collimated light.
[9] An aspect 9 of the present invention may be the semiconductor device handling apparatus of any one of the aspects 1 to 8, wherein the second transmission portion is separated from the first transmission portion when the holding portion makes contact with the terminal and the contact portion.
[10] An aspect 10 of the present invention may be the semiconductor device handling apparatus of any one of the aspects 1 to 6, wherein the second transmission portion is in contact with the first transmission portion when the holding portion makes contact with the terminal and the contact portion.
[11] An aspect 10 of the present invention may be the semiconductor device handling apparatus of any one of the aspects 1 to 10, wherein the holding portion comprises: a main body including an opposing surface that faces the second surface of the DUT; and a suction holding mechanism opening on the opposing surface and holding the DUT by suction.
[12] An aspect 12 of the present invention may be the semiconductor device handling apparatus of any one of the aspects 1 to 11, wherein the semiconductor device handling apparatus comprises a contact arm holding the holding portion and moves the holding portion relative to the contact portion, and the holding portion is detachably held at a tip of the contact arm.
[13] An aspect 13 of the present invention is a semiconductor device testing apparatus testing a DUT, comprising: the semiconductor device handling apparatus of any one of the aspects 1 to 12; and a tester testing the DUT, wherein the tester comprises: a contact portion inputting and outputting an electrical signal to and from the terminal; and a first transmission portion inputting and outputting a signal to and from the second transmission portion.
[14] An aspect 14 of the present invention is a semiconductor device testing apparatus testing a DUT, comprising: the semiconductor device handling apparatus of the aspect 7; and a tester testing the DUT, wherein the tester comprises: a contact portion inputting and outputting an electrical signal to and from the terminal; and a first transmission portion inputting and outputting a signal to and from the second transmission portion, the first transmission portion comprises: a third emission portion emitting the first optical signal to the first incident portion; and a fourth lens disposed between the second transmission portion and the third emission portion and converting the first optical signal emitted from the third emission portion into a collimated light.
[14] An aspect 15 of the present invention is a semiconductor device testing apparatus testing a DUT, comprising: the semiconductor device handling apparatus of the aspect 8; and a tester testing the DUT, wherein the tester comprises: a contact portion inputting and outputting an electrical signal to and from the terminal; and a first transmission portion inputting and outputting a signal to and from the second transmission portion, the first transmission portion comprises: a third incident portion receiving the fourth optical signal from the first emission portion; and a third lens disposed between the second transmission portion and the third incident portion and condensing the fourth optical signal at the third incident portion.
[14] An aspect 16 of the present invention may be the semiconductor device testing apparatus of any one of the aspects 13 to 15, wherein the contact portion comprises a socket disposed on a test head, the socket comprises: a contactor contacting the terminal; and the first transmission portion positioned outside of the contactor.

### EFFECT OF THE INVENTION

According to the present invention, the second transmission section can transmit a signal between the optical connection portion of the DUT and the first transmission portion of the tester. Therefore, it is possible to provide the semiconductor device handling apparatus and the semiconductor device testing apparatus for testing the semiconductor device with the electronic and optical circuits.

### BRIEF DESCRIPTION OF DRAWING(S)

FIG. 1 is a diagram showing the overall configuration of the semiconductor device testing apparatus according to one or more embodiments of the present invention;

FIG. 2 is a cross-sectional view showing II portion of FIG. 1 and a state of the semiconductor device testing apparatus before the DUT is pressed against the socket;

FIG. 3 is a cross-sectional view showing II portion of FIG. 1 and a state of the semiconductor device testing apparatus after the DUT is pressed against the socket;

FIG. 4 is a plan view of the socket in one or more embodiments of the present invention;

FIG. 5 is a bottom view of the pusher in one or more embodiments of the present invention;

FIG. 6 is a cross-sectional view showing the portion corresponding to II portion of FIG. 1 one or more embodiments of the present invention and showing a state of the semiconductor device testing apparatus before the DUT is pressed against the socket; and

FIG. 7 is a cross-sectional view showing the portion corresponding to II portion of FIG. 1 one or more embodiments of the present invention and showing a state of the semiconductor device testing apparatus after the DUT is pressed against the socket.

### MODE(S) FOR CARRYING OUT THE INVENTION

Hereinafter, embodiments of the invention will be described with reference to the drawings.

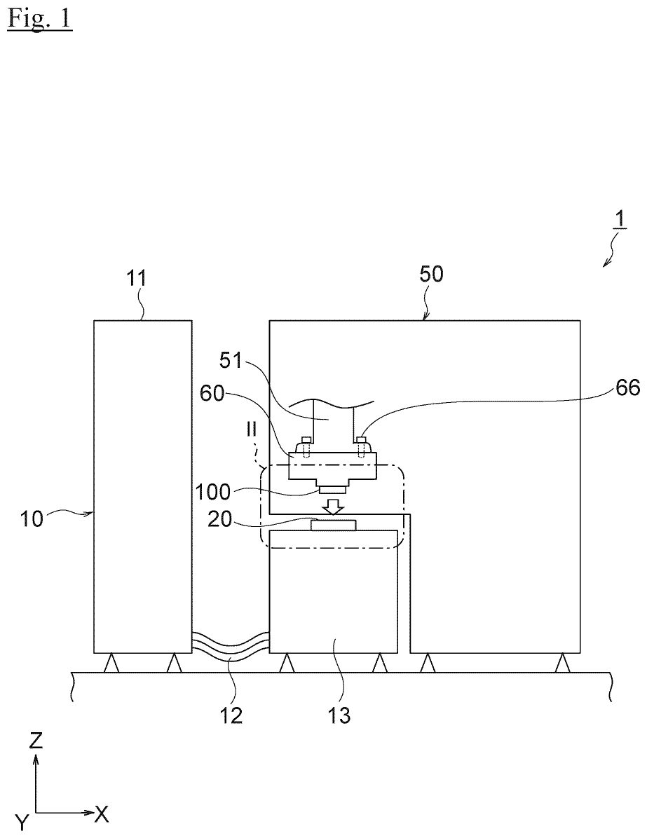

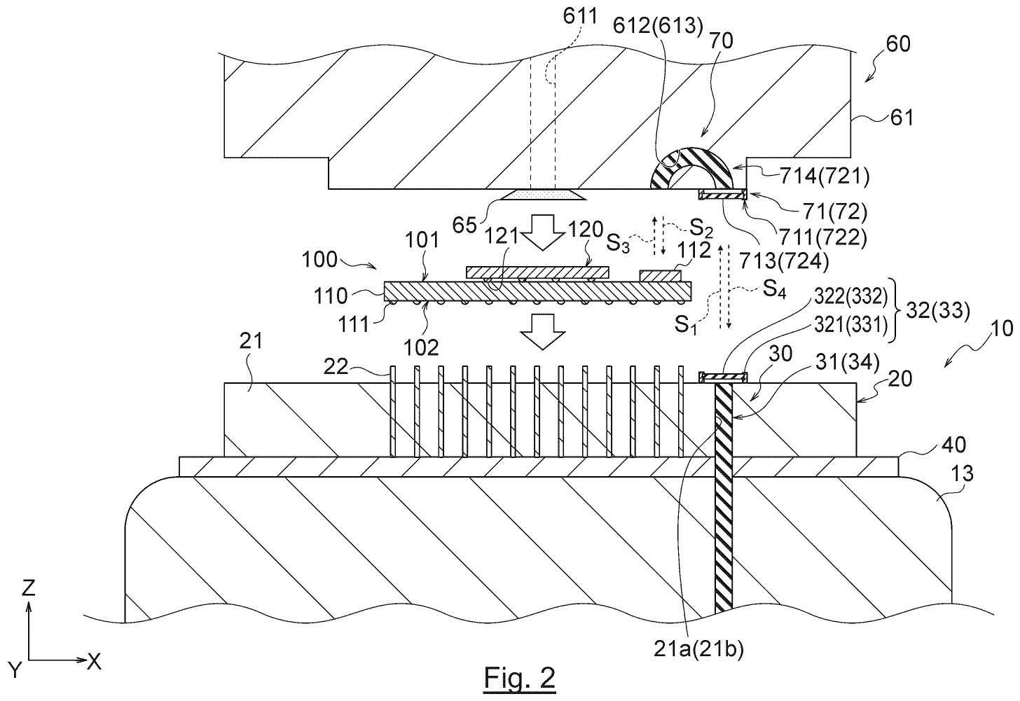

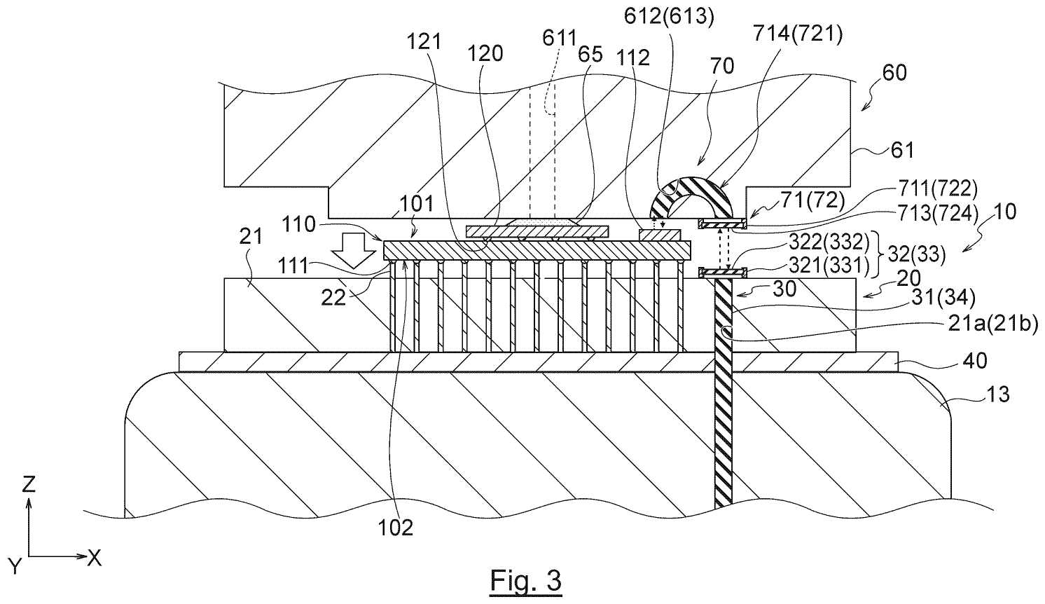

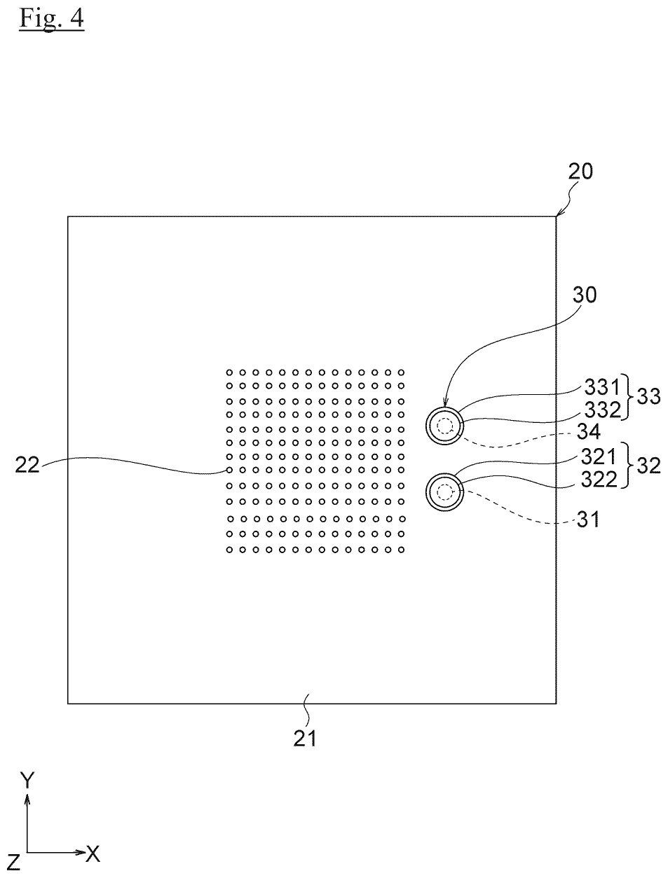

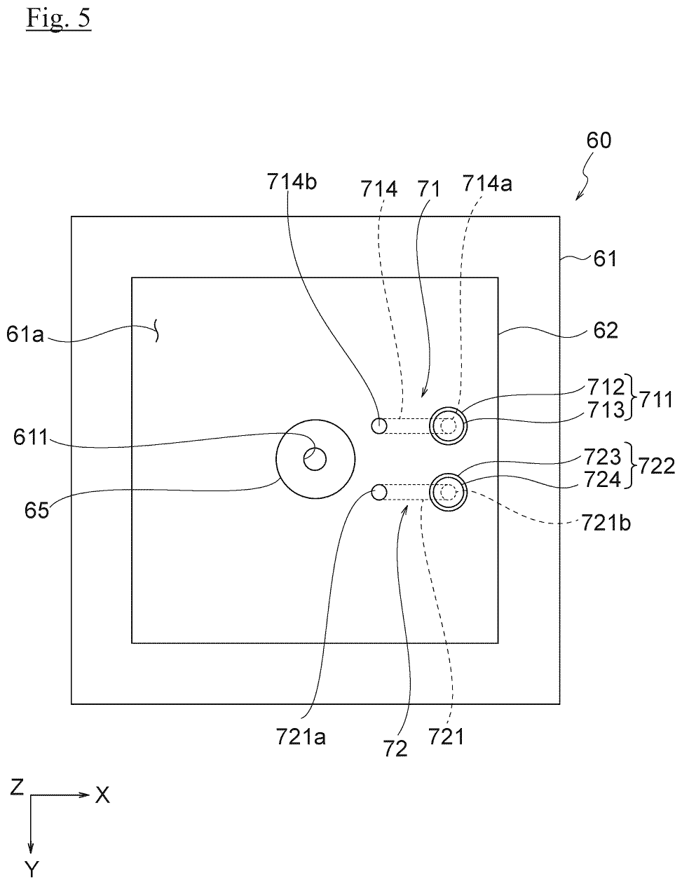

FIG. 1 is a diagram showing the overall configuration of the semiconductor device testing apparatus 1 in one or more embodiments. FIG. 2 is a cross-sectional view showing II portion of FIG. 1 and a state of the semiconductor device testing apparatus 1 before the DUT 100 is pressed against the socket 20. FIG. 3 is a cross-sectional view showing II portion of FIG. 1 and a state of the semiconductor device testing apparatus 1 after the DUT 100 is pressed against the socket 20. FIG. 4 is a plan view of the socket 20. FIG. 5 is a bottom view of the pusher 60. For ease of understanding, the DUT 100 is separated from the pusher 60 in FIG. 2, but in reality, the DUT 100 is in contact with the pusher 60 because the DUT 100 is held by the pusher 60.

The semiconductor device testing apparatus 1 in one or more embodiments is an apparatus for testing the DUT 100. As shown in FIG. 1, this semiconductor device testing apparatus 1 includes a tester 10 and a handler 50. This handler 50 corresponds to an example of “a semiconductor device handling device” in the aspect of the present invention.

The DUT 100, which is the object to be tested by the semiconductor device test apparatus 1, is a semiconductor device capable of dealing electrical signals and optical signals. In other words, this DUT 100 is a composite circuit device with electronic and optical circuits.

Specifically, as shown in FIG. 2, the DUT 100 in one or more embodiments includes a substrate 110 and an IC chip 120. Although an example of the substrate 110 is not limited, a wiring board such as an interposer may be used.

The substrate 110 includes terminals 111 and an optical connection portion 112. The terminals 111 are provided on a bottom surface 102 of the substrate 110. As shown in FIG. 3, the terminals 111 are electrically connected to contactors 22 of the socket 20 by making contact with the contactors 22. Thereby, the DUT 100 is electrically connected to a test head 13 of a tester 10 (see below). The terminals 111 are used to input electrical signals from the test head 13 to the electronic circuit of the DUT 100 and to output electrical signals from the electronic circuit to the test head 13. The bottom surface 102 corresponds to an example of “a first surface” in the aspect of the present invention.

As shown in FIG. 2, the optical connection portion 112 is disposed on a top surface 101 of the substrate 110. As shown in FIG. 3, the optical connection portion 112 is used to output and input optical signals to and from the DUT 100. Although not particularly limited, the optical connection portion 112 in one or more embodiments is separated from a second transmission portion (holder transmitter) 70 (see below) when the terminals 111 are in contact with the contactors 22. Although not particularly limited, an example of this optical connection portion 112 may be a device with a grating coupler. Alternatively, the optical connection portion 112 may be an optical socket or a connector that can input and output light and can be connected to an optical fiber or the like. The optical connection portion 112 may be in contact with the second transmission portion 70 when the terminals 111 are in contact with the contactors 22. The top surface 101 corresponds to an example of a “second surface” in the aspect of the present invention.

Although not specifically shown in the figures, an optical module equipped with an optical circuit having the functions of converting optical signals into electrical signals and converting electrical signals into optical signals is interposed between the optical connection portion 112 and the substrate 110. At this optical module, an optical signal input from the optical connection 112 is converted into an electrical signal and output to the substrate 110, while an electrical signal input from the substrate 110 is converted into an optical signal and output to the optical connection portion 112.

The IC chip 120 is mounted on the top surface 101 of the substrate 110. The kind of this IC chip 120 may be changed according to the design of the DUT 100. One example, but not limited to, is an ASIC (Application Specific Integrated Circuit), etc. The IC chip 120 includes terminals 121 and is electrically connected to the substrate 110 through the terminals 121, and is electrically connected to the substrate 110 via the terminals 121.

During the testing of the DUT 100, electrical signals are input to the DUT 100 and output from the DUT 100 via the terminals 111, and optical signals are input to the DUT 100 output from the DUT 100 via the optical connection portion 112. Once this testing is completed, for example, the optical fiber connected to the optical connector is connected to the optical connection portion 112, resulting in a final product. This final product is, for example, a CPO (Co-Packaged Optics) device.

The DUT 100 to be tested in the semiconductor device testing apparatus 1 of one or more embodiments is not limited to those described above. For example, the DUT 100 may include an interposer with terminals 111 and a die mounted on the interposer. The die is a bare die (bare chip) formed by dicing a semiconductor wafer and is equipped with an optical connection portion 112 for inputting and outputting optical signals.

Alternatively, the DUT 100 may be a bare die with the terminals 111 and the optical connection portion 112. In other words, the DUT 100 to be tested may be one die before it is mounted on a substrate. Alternatively, the DUT 100 may be part of a semiconductor wafer. That is, an individual DUT 100 of the semiconductor wafer on which the DUTs 100 are formed may be the test object. For example, the individual semiconductor wafer may have the terminal 111 on the bottom surface and the optical connection portion 112 on the top surface.

The tester (main body of testing apparatus) 10 is a testing apparatus that tests the DUT 100 using electrical and optical signals. As shown in FIG. 1, the tester 10 includes a main frame (a main body of the tester) 11, a cable 12, a test head 13, the socket 20, and a load board (a performance board) 40 (see FIG. 2). The socket 20 corresponds to an example of “a contact portion” in the aspect of the present invention.

For example, the mainframe 11 is a computer that executes programs and communicates with the respective test modules (pin electronics cards) (not shown) in the test head 13 according to the programs to control the respective test modules.

The test head 13 is connected to the main frame 11 via the cable 12. This test head 13 houses the test modules that test the DUT 100. Each test module generates test signals in response to instructions from the main frame 11 and outputs those test signals to the DUT 100.

The test module in one or more embodiments can transfer electrical signals as test signals to and from the electronic circuit of the DUT 100 via the load board 40 and the socket 20. Furthermore, the test module can transfer optical signals as test signals to and from the optical connection portion 112 via a first transmission portion (tester transmitter) 30 and the second transmission portion 70. The tester 10 can test the DUT 100 by using this test modules to transfer and receive electrical and optical signals.

As shown in FIGS. 2 to 4, the socket 20 has a socket body 21, contactors 22, and the first transmission portion 30. The socket body 21 is fixed to the top surface of the test head 13 via the load board 40. The contactors 22 are held in this socket body 21.

The contactor 22 is electrically connected to the load board 40 disposed on the top surface of the test head 13. This contactor 22 is also electrically connected to the DUT 100 by contacting the terminal 111 of the DUT 100. The electrical signals as the test signals are input to the DUT 100 via this contactor 22. In one or more embodiments, a pogo pin is used as the contactor 22, but something other than a pogo pin may be used as the contactor 22. For example, a cantilever-type probe needle, an anisotropic conductive rubber sheet, or a membrane-type contactor with bumps formed on an insulating film may be used as the contactor 22.

The first transmission portion 30 is disposed in the socket body 21 in one or more embodiments. The first transmission portion 30 in one or more embodiments transmits the first optical signal S₁ as a test signal to the second transmission portion 70 (see below) and receives the fourth optical signal S₄ as an output signal emitted from the second transmission portion 70 when the DUT 100 is tested. The first transmission portion 30 corresponds to an example of “a first transmission portion” or “a tester transmitter” in the aspect of the present invention, and the second transmission portion 70 corresponds to an example of “a second transmission unit” or “a holder transmitter” in the aspect of the present invention.

The first transmission portion 30 is disposed outside of the contactor 22 in the socket 20. Therefore, the first transmission portion 30 is facing the second transmission portion 70 and not facing the DUT 100. The first transmission portion 30 transmits optical signals between the tester 10 and the second transmission portion 70 when the pusher 60 is in contact with the terminal 111 of the DUT 100 and the socket 20.

The first transmission portion 30 includes a first optical fiber 31, a first collimating portion 32, a first condensing portion 33, and a second optical fiber 34. The first optical fiber 31 corresponds to an example of “a third emission portion” in the aspect of the present invention, and the second optical fiber 34 corresponds to an example of “a third incident portion” in the aspect of the present invention.

As shown in FIGS. 2 and 3, the first optical fiber 31 is disposed inside the first retaining hole 21a formed in the socket body 21 and is retained in the first retaining hole 21a. The first retaining hole 21a penetrates the socket body 21 in a thickness direction, and the first optical fiber 31 also extends along the thickness direction of the socket body 21.

The first optical fiber 31 optically connects the first transmission portion 30 to the tester 10. This first optical fiber 31 emits the first optical signal S₁ as a test signal output by the tester 10 from an emission end surface (a top end surface) toward the second transmission portion 70 when the DUT 100 is tested. Although not limited, the diameter of the first optical signal S₁ emitted from the emission end surface of the first optical fiber 31 gradually expands as it approaches the first collimating portion 32.

In one or more embodiments, for example, the first optical fiber 31 and the second optical fiber 34 of the first transmission portion 30 may extend to the interior of the test head 13 and directly output and input optical signals from the test head 13. Otherwise, the first optical fiber 31 and the second optical fiber 34 of the first transmission portion 30 may extend to the interior of the test head 13 and the main frame 11, and optical signals may be directly output and input to and from the main frame 11. In these cases, the test head 13 or main frame 11 may include a light emitting element that emits an optical signal as a test signal into the first optical fiber 31 and a light receiving element that receives an optical signal as an output signal from the second optical fiber 34. The test head 13 or main frame 11 may have a function of evaluating the test results based on the optical signals received by the light receiving element.

The tester 10 may not have a function to test the DUT 100 with optical signals. In this case, an external measuring device with a function to test the optical circuit of the DUT 100 may be connected to the first and third optical fibers 31, 714 of the first transmission portion 30 to send and receive optical signals. For example, this external measuring device may be a test device independent of the tester 10 and may be electrically connected to the tester 10.

The first collimating portion 32 collimates the first optical signal S₁ emitted from the first optical fiber 31. In other words, the first collimating portion 32 is a collimator that collimates the first optical signal S₁. The first collimating portion 32 includes a lens holding portion 321 and a first collimating lens 322. The first collimating lens 322 corresponds to an example of “a fourth lens” in the aspect of the present invention.

As shown in FIG. 4, the lens holding portion 321 is disposed on the top surface of the socket body 21. This lens holding portion 321 includes a cylindrical shape, and can hold the first collimating lens 322 in the inner space of the lens holding portion 321.

The first collimating lens 322 in one or more embodiments is fitted inside the lens holding portion 321. This first collimating lens 322 converts the first optical signal S₁ emitted from the first optical fiber 31 into a collimated light. As the first collimating lens 322, it is not limited, but a double-sided convex lens etc. may be used. Thus, the first collimating lens 322 can convert the first optical signal S₁ emitted from the first optical fiber 31 into the collimated light with a larger diameter. Therefore, since the first optical signal S₁ can be made into the collimated light with the larger diameter, the tolerance for misalignment of the first optical signal S₁ with respect to the third optical fiber 714 (described below) of the second transmission portion 70 can be increased.

As shown in FIG. 4, the first condensing portion 33 focuses the fourth optical signal S₄ emitted from the fourth optical fiber 721 (see below) of the second transmission portion 70 on the second optical fiber 34. In other words, the first condensing portion 33 reduces the diameter of the fourth optical signal S₄ and focuses the fourth optical signal S₄ on the second optical fiber 34. The first condensing portion 33 includes a lens holding portion 331 and a first condensing lens 332.

The lens holding portion 331 is disposed on the top surface of the socket body 21. This lens holding portion 331 has a cylindrical shape and can hold the first condensing lens 332 in the inner space of the lens holding portion 331.

The first condensing portion 332 is fitted inside the lens holding portion 331. This first condensing lens 332 focuses the fourth optical signal S₄ emitted from the fourth optical fiber 721 of the second transmission portion 70 on the incident end surface (a top end surface) of the second optical fiber 34. As the first condensing lens 332, it is not limited, but a double-sided convex lens capable of condensing incident light may be used. Thus, the fourth optical signal S₄ emitted toward the first condensing portion 33 is focused by the first condensing lens 332 on the incident end surface of the second optical fiber 34, thereby suppressing transmission loss of the fourth optical signal S₄.

The second optical fiber 34 is injected with the fourth optical signal S₄ when the DUT 100 is tested. As with the first optical fiber 31, this second optical fiber 34 is disposed inside the second holding hole 21b formed in the socket body 21 and is held in the second holding hole 21b. The fourth optical signal S₄ incident on the incident end surface of the second optical fiber 34 propagates inside the second optical fiber 34 and enters the tester 10.

In one or more embodiments, the first transmission portion 30 is disposed in the socket 20, but is not limited to this. The first transmission portion 30 may be provided away from the socket 20, for example, on the top surface of the load board 40, or on the top surface of the test head 13, etc. In these case, the first transmission portion 30 may be provided away from the socket 20.

The load board 40 is mounted on the top surface of the test head 13 and is electrically connected to the test head 13. The socket 20 is mounted on this load board 40, and when the DUT 100 is pressed against the socket 20 by the handler 50, the DUT 100 is electrically connected to the tester 10 via the socket 20 and load board 40.

As shown in FIG. 1, the handler 50 includes a contact arm 51 and the pusher 60. The pusher 60 corresponds to an example of “a holding portion” or “a holder” in the aspect of the present invention.

The contact arm 51 is supported on a rail (not shown) provided in the handler 50. The contact arm 51 moves relative to the socket 20. Specifically, the contact arm 51 is equipped with an actuator (not shown) for horizontal movement and can move back and forth, left and right according to the rail. The contact arm 51 is also equipped with an actuator (not shown) for vertical drive and can move vertically.

The pusher 60 is detachably held at the lower end of the contact arm 51. Although not limited, the pusher 60 in one or more embodiments is detachably held at the lower end of the contact arm 51 by bolts 66.

As shown in FIGS. 2 and 3, the pusher 60 includes a pusher body 61, a suction pad 65, and the second transmission portion 70. The pusher body 61 corresponds to an example of “a main body” in the aspect of the present invention.

The pusher body 61 includes a suction hole 611, a third holding hole 612, and a fourth holding hole 613. The suction hole 611 is a through hole opening at the bottom surface 61a of the pusher body 61. The bottom surface 61a faces the top surface 101 of the DUT 100. The suction hole 611 is connected to an unshown vacuum pump, and the interior of the suction hole 611 is made negative pressure by this vacuum pump. The bottom surface 61ₐ corresponds to an example of “an opposing surface” in the aspect of the present invention.

The third holding hole 612 is a through hole opening at two locations on the bottom surface 61a of the pusher body 61 and extending in an abbreviated U-shape. The third holding hole 612 holds the third optical fiber 714 described below. Similar to the third holding hole 612, the fourth holding hole 613 is also a through hole opening at two locations on the bottom surface 61a of the pusher body 61 and extending in an abbreviated U-shape. The fourth holding hole 613 holds the fourth optical fiber 721 described below.

On the bottom surface 61a of the pusher body 61, the suction pad 65 is disposed on a position corresponding to the position of the suction hole 611. The inside of the suction pad 65 is made to be under negative pressure by a vacuum pump (not shown) through the suction hole 611, and the suction pad 65 sucks and holds the top surface 101 of the DUT 100. The suction holding mechanism including the suction hole 611 and the suction pad 65 corresponds to an example of “a suction holding mechanism” in the aspect of the present invention.

The second transmission portion 70 is disposed in the pusher body 61. The second transmission portion 70 in one or more embodiments transmits the optical signals between the first transmission portion 30 and the optical connection portion 112.

As shown in FIGS. 2, 3, and 5, this second transmission portion 70 includes a first light transmission unit 71 and a second light transmission unit 72. The first light transmission unit 71 corresponds to an example of “a first light transmission portion” or “a first light transmitter” in the aspect of the present invention, and the second light transmission unit 72 corresponds to an example of “a second light transmission portion” or “a second light transmitter” in the aspect of the present invention.

The first optical transmission unit 71 is injected with the first optical signal S₁ from the first optical fiber 31 of the first transmission portion 30 and emits the second optical signal S₂ to the optical connection portion 112 when the DUT 100 is tested. This first optical transmission unit 71 has a second condensing portion 711 and a third optical fiber 714. The third optical fiber 714 corresponds to an example of the “first incident portion,” the “first optical transmission line,” and the “second ejection portion” in the present manner.

The second condensing portion 711 is positioned between the first transmission portion 30 and the third optical fiber 714 and focuses the first optical signal S₁ converted to the collimated light by the first collimating lens 322 on the incident end surface 714a of the third optical fiber 714 (see FIG. 5). In other words, the second condensing portion 711 reduces the diameter of the first optical signal S₁ and focuses the first optical signal S₁ on the incident end surface 714a of the third optical fiber 714. The second condensing portion 711 has a lens holding portion 712 and a second condensing lens 713.

The lens holding portion 712 is disposed on the bottom surface 61a of the pusher body 61. The lens holding portion 712 has a cylindrical shape, and a second condensing portion 713 can be held in the inner space of the lens holding portion 712.

The second condensing portion 713 is fitted inside the lens holding portion 712. This second condensing lens 713 is positioned between the first collimating lens 322 and the third optical fiber 714, and focuses the first optical signal S₁ converted to the collimated light by the first collimating lens 322 on the third optical fiber 714. As the second condensing lens 713, it is not limited, but a double-sided convex lens capable of focusing incident light may be used. Thus, the first optical signal S₁ is focused by the second focusing lens 713 on the incident end surface 714a of the third optical fiber 714, thereby suppressing transmission loss of the first optical signal S₁.

The third optical fiber 714 is provided inside the third holding hole 612. In this third optical fiber 714, the focused first optical signal S₁ is incident on the incident portion 714a facing the first optical fiber 31, and this first optical signal S₁ propagates inside the third optical fiber 714, and is emitted from the emission end surface 714b (see FIG. 5) facing the optical connection portion 112 to the optical connection portion 112 as the second optical signal S₂. The second optical signal S₂ in one or more embodiments is the first optical signal S₁ propagated inside the third optical fiber 714 and is the same optical signal as the first optical signal S₁.

As shown in FIG. 5, the incident end surface 714a is positioned outside of the emission end surface 714b on the bottom surface 61a of the pusher body 61. The incident end surface 714a of the third optical fiber 714 faces the first optical fiber 31 of the first transmission portion 30 (see FIGS. 2 to 4), while the emission end surface 714b faces the optical connection portion 112 of the DUT 100.

Although not limited, the position of the pusher 60 can be mechanically aligned with respect to the socket 20 in order to face the incident end surface 714a of the third optical fiber 714 with the first optical fiber 31 of the first transmission portion 30. For example, an unshown alignment pin is provided on the pusher 60 and a mating hole corresponding to the alignment pin is provided on the socket 20, and when the DUT 100 is pressed against the socket 20 by the pusher 60, the alignment pin is fitted into the mating hole. Thereby, the relative position of the pusher 60 and the socket 20 can be adjusted so that the incident end face 714a and the first optical fiber 31 face each other.

In order to make the emission end surface 714b and the optical connection portion 112 face each other, the alignment may be performed using image processing. For example, although this is not particularly limited, when the DUT 100 is sucked by the pusher 60, a camera or other imaging device can be used to detect the position of the emission end surface 714b and the optical connection portion 112, and the detected image can be used to adjust the relative position of the pusher 60 and the DUT 100 so that the emission end surface 714b and the optical connection portion 112 face each other.

Alternatively, although this is not particularly limited, the positional relationship between the emission end surface 714b and the optical connection portion 112 may be recognized based on, for example, the intensity of light output from the optical connection portion 112. For example, an alignment apparatus with a light emitting element and a light receiving element can be used. Specifically, light is emitted from the light emitting element of this alignment apparatus toward the top surface 101 of the DUT 100 via the third optical fiber 714 of the second transmission portion 70. The light output from the optical connection portion 112 via a loopback circuit incorporated in the optical circuit of the DUT 100 is then received by the light receiving element of the alignment apparatus via the fourth optical fiber 721 of the second transmission portion 70. While performing this operation, the fourth optical fiber 721 is scanned along the top surface 101 of the DUT 100 by moving the pusher 60 with the contact arm 51. The intensity of the light output from the optical connection portion 112 is measured by the alignment apparatus, and by stopping the movement of the contact arm 51 at the position where the intensity of the light exceeds a predetermined value, thereby the emission end surface 714b of the third optical fiber 714 is aligned with respect to the optical connection portion 112. This also allows the alignment of the incident end surface 721a of the fourth optical fiber 721 and the optical connection portion 112, described below, to be completed at the same time.

As shown in FIGS. 2, 3, and 5, the second optical transmission unit 72 receives the third optical signal S₃ from the optical connection portion 112 of the DUT 100 and emits a fourth optical signal S₄ into the second optical fiber 34 of the first transmission portion 30 when the DUT 100 is tested. This second optical transmission unit 72 includes a fourth optical fiber 721 and a second collimating portion 722. The fourth optical fiber 721 corresponds to an example of “a second incident portion”, “a second optical transmission path” and “a first emission portion” in the aspect of the present invention.

The fourth optical fiber 721 is injected with a third optical signal S₃ from the optical connection portion 112 to the incident end surface 721a (see FIG. 5) when the DUT 100 is tested. This third optical signal S₃ is the optical signal that the DUT 100 emits in response to the electrical signal input from the tester 10 or the second optical signal S₂ described above.

In this fourth optical fiber 721, the third optical signal S₃ emitted from the optical connection portion 112 is injected into the incident end surface 721a, and the injected third optical signal S₃ propagates inside the fourth optical fiber 721. The propagated third optical signal S₃ is then ejected from the emission end surface 721b (see FIG. 5) to the second optical fiber 34 as the fourth optical signal S₄. Although not limited, the diameter of the fourth optical signal S₄ ejected from the emission end surface of the fourth optical fiber 721 gradually expands as it approaches the second collimating portion 722. The fourth optical signal S₄ in one or more embodiments is the same as the third optical signal S₃ that propagated inside the fourth optical fiber 721.

As shown in FIG. 5, the incident end surface 721a of the fourth optical fiber 721 is disposed more inward than the discharge end face 721b on the bottom surface 61a of the pusher body 61. The incident end surface 721a faces the optical connection portion 112 (see FIGS. 2 to 4) of the DUT 100, while the emission end surface 721b faces the second optical fiber 34 of the first transmission portion 30. The incident end surface 721a and the optical connection portion 112 can be opposed by the image processing and light intensity-based alignment methods described above, while the emission end surface 721b and the second optical fiber 34 can be opposed by the mechanical positioning described above.

As shown in FIGS. 2, 3, and 5, the second collimating portion 722 collimates the fourth optical signal S₄ emitted from the fourth optical fiber 721. This second collimating portion 722 includes a lens holding portion 723 and a second collimating lens 724. The second collimating lens 724 corresponds to an example of “a second lens” in the aspect of the present invention.

The lens holding portion 723 is disposed on the bottom surface 61a of the pusher body 61. This lens holding portion 321 has a cylindrical shape and can hold the second collimating lens 724 in the inner space of the lens holding portion 723.

The second collimating lens 724 in one or more embodiments is fitted inside the lens holding portion 723. This second collimating lens 724 converts the fourth optical signal S₄ emitted from the fourth optical fiber 721 into a collimated light. As the second collimating lens 724, it is not particularly limited, but a double-sided convex lens can be used. Thus, the second collimating lens 724 can make the fourth optical signal S₄ into the collimated light with a large diameter, thereby the tolerance for misalignment of the fourth optical signal S₄ with respect to the second optical fiber 34 of the first transmission portion 30 can be increased.

In the semiconductor device test apparatus 1 in one or more embodiments as shown in FIGS. 2 and 3, testing of the DUT 100 is performed in the following manner, without limitation. The handler 50 includes a holding portion (not shown) such as a tray or buffer, in which the DUT 100 is held before testing. The contact arm 51 aligns the pusher 60 with respect to the DUT 100 held in this holding portion using the alignment method using image processing or based on light intensity described above, and the DUT 100 is sucked and held by the pusher 60. At this time, the emission end surface 714b of the third optical fiber 714 and the incident end surface 721a of the fourth optical fiber 721 face the optical connection portion 112 of the DUT 100.

Next, the contact arm 51 moves the pusher 60 holding the DUT 100 to above the socket 20, and then lowers the pusher 60 toward the socket 20. Thereby the terminals 111 of the DUT 100 contact with the contactors 22 of the socket 20. At this time, the DUT 100, pusher 60, and socket 20 are aligned by the-above mechanical positioning method. As a result, the top end surface (the emission end surface) of the first optical fiber 31 faces the emission end surface 714a of the third optical fiber 714, and the top end surface (the emission end surface) of the second optical fiber 34 faces the emission end face 721b of the fourth optical fiber 721.

In this state, the electrical signals are input and output between the tester 10 and the DUT 100 via the contactors 22 and the terminals 111, and the optical signals are input and output between the tester 10 and the DUT 100 via the first and second transmission portions 30, 70 and optical connection portion 112. In this way, the tester 10 tests the DUT 100 by making both electrical and optical signals input and output between the tester 10 and the DUT 100.

According to the-above semiconductor device testing apparatus 1, since the second transmission portion 70 can transmit signals between the optical connection portion 112 of the DUT 100 and the first transmission portion 30 of the tester 10, it possible to test a DUT 100 with the electronic circuit and the optical circuit. In particular, in one or more embodiments, the semiconductor device testing apparatus 1 can test the DUT 100 having the terminals 111 disposed on the top surface 101 of the DUT 100 and the optical connection portion 112 disposed on the bottom surface 102 of the DUT 100.

It should be noted that the embodiments described above are described to facilitate understanding of the present disclosure and are not described to limit the present disclosure. It is therefore intended that the elements disclosed in the above embodiments include all design modifications and equivalents to fall within the technical scope of the present disclosure.

For example, in the above embodiments, the optical signals are transmitted between the tester 10 and the DUT 100 in a state where the first transmission portion 30 and the second transmission portion 70 are separated, but this is not limited. The optical signals may be transmitted in a state where the first transmission portion 30 and the second transmission portion 70 are in contact.

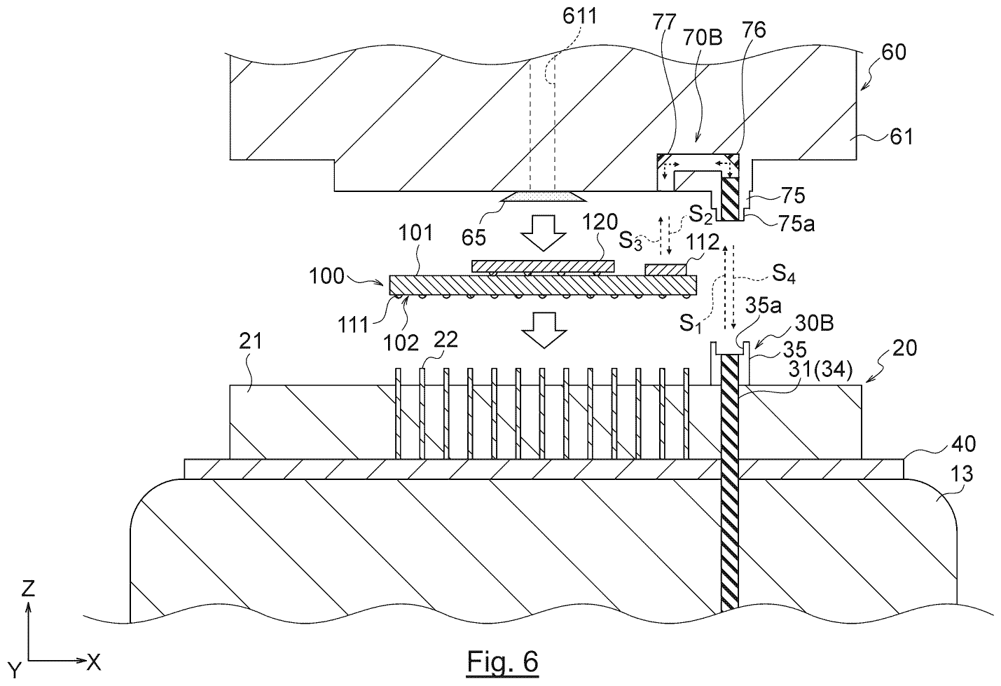

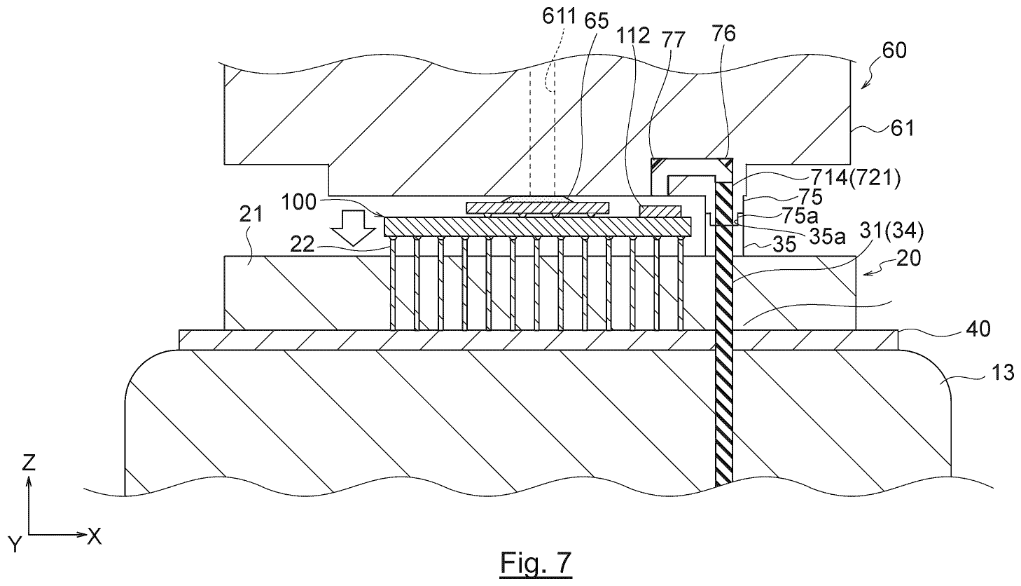

FIG. 6 is a cross-sectional view showing the portion corresponding to II portion of FIG. 1 in one or more embodiments of the present invention and showing a state of the semiconductor device testing apparatus 1 before the DUT 100 is pressed against the socket 20. FIG. 7 is a cross-sectional view showing the portion corresponding to II portion of FIG. 1 in one or more embodiments of the present invention and showing a state of the semiconductor device testing apparatus 1 after the DUT 100 is pressed against the socket 20.

As shown in FIGS. 6 and 7, the first transmission portion 30B includes first mating portions 35, 35 having concave portions 35a around each of the first and second optical fibers 31, 34, and the second transmission portion 70B includes second mating portion 75, 75 having convex portions 75a around each of the third and fourth optical fibers 714, 721. In other words, in one or more embodiments, the concave-convex mating causes the first transmission portion 30B to contact the second transmission portion 70B, causes the first optical fiber 31 to contact the third optical fiber 714, and causes the second optical fiber 34 to contact the fourth optical fiber 721. In this case, the first optical signal S₁ and the fourth optical signal S₄ are input and output at the contacting end surfaces of the optical fibers.

In the above embodiments, in the second transmission portion 70, the third and fourth optical fibers 714, 721 are curved into an abbreviated U-shape to reverse the incidence and emission directions of the optical signals, but this is not limited to this. For example, as shown in FIGS. 6 and 7, the incident direction and the ejection direction of the optical signals may be controlled by reflecting the optical signal using mirrors 76, 77. When the optical fibers are in contact with each other as in the embodiments in FIGS. 6 and 7, the incident and emission directions of the optical signals may be adjusted by curving the optical fiber in the second transmission portion 70 without using a mirror, as in the embodiments shown in FIGS. 2 and 3.

In the above embodiments, the optical signals are input and output between the first transmission portion 30 and the second transmission portion 70, but this is not limited to this. The electrical signals may be input and output between the first transmission portion 30 and the second transmission portion 70. For example, the second transmission portion 70 may receive an electrical signal from the first transmission portion 30, convert the electrical signal into an optical signal using a photoelectric conversion element or the like, and emit the converted optical signal to the optical connection portion 112. Further, the second transmission portion 70 may receive an optical signal from the optical connection portion 112, convert the optical signal into an electrical signal using the photoelectric conversion element or the like, and output the converted electrical signal to the first transmission portion 30.

In the above embodiments, the case in which the semiconductor device testing apparatus 1 includes a pair of the first transmission portion 30 and the second transmission portion 70 is illustrated, but is not limited to this. In cases where there are multiple inputs of the optical signals to and multiple outputs of the optical signals from the semiconductor device 100, etc., the semiconductor device testing apparatus 1 may include multiple pairs of the first transmission portion 30 and the second transmission portion 70.

### EXPLANATIONS OF LETTERS OR NUMERALS

1 . . . Semiconductor device testing apparatus
10 . . . Tester
11 . . . Main frame
12 . . . Cable
13. Test head
20 . . . Socket
21 . . . Socket body
21a, 21b . . . First and second holding holes
22 . . . Contactor
30, 30B . . . First transmission portion
31 . . . First optical fiber
32 . . . First collimating portion
321 . . . Lens holding portion
322 . . . First collimating lens
33 . . . First condensing portion
331 . . . Lens holding portion
332 . . . First condensing lens
34 . . . Second optical fiber
35 . . . First mating portion
35a . . . Concave portion
40 . . . Load Board
50 . . . Handler
51 . . . Contact arm
60 . . . Pusher
61 . . . Pusher body
611 . . . Suction hole
612, 613 . . . Third and fourth holding holes
65 . . . Suction pad
66 . . . Bolt
70, 70B . . . Second transmission portion
71 . . . First optical transmission unit
711 . . . Second condensing portion
712 . . . Lens holding portion
713 . . . Second condensing lens
714 . . . Third optical fiber
72 . . . Second optical transmission unit
721 . . . Fourth optical fiber
722 . . . Second collimating portion
723 . . . Lens holding portion
724 . . . Second collimating lens
75 . . . Second mating portion
75a . . . Convex portion
76, 77 . . . Mirrors
100 . . . Semiconductor device
101 . . . Top surface
102 . . . Bottom surface
110 . . . Substrate
111 . . . Terminal
112 . . . Optical connection portion
120 . . . IC chip

What is claimed is:

1. A semiconductor device handling apparatus that handles a device under test (DUT) to bring a terminal disposed on a first surface of the DUT into contact with a contact portion of a tester comprising a tester transmitter, the semiconductor device handling apparatus comprising:
a holder that holds a second surface of the DUT, wherein
the holder comprises a holder transmitter that transmits a signal between an optical connection portion disposed on the second surface of the DUT and the tester transmitter, and
the holder transmitter inputs and outputs an optical signal to and from the optical connection portion.

2. The semiconductor device handling apparatus according to claim 1, wherein the holder transmitter inputs and outputs an optical signal to and from the tester transmitter.

3. The semiconductor device handling apparatus according to claim 1, wherein the holder transmitter comprises:
a first optical transmitter that receives a first optical signal from the tester transmitter and emits a second optical signal to the optical connection portion; and
a second optical transmitter that receives a third optical signal from the optical connection portion and emits a fourth optical signal to the tester transmitter.

4. The semiconductor device handling apparatus according to claim 3, wherein
the holder comprises a main body including an opposing surface that opposes the second surface of the DUT,
the first optical transmitter comprises a first incident portion that receives the first optical signal,
the second optical transmitter comprises a first emission portion that emits the fourth optical signal, and
the first incident portion and the first emission portion are disposed on the opposing surface such that the first incident portion and the first emission portion face the tester transmitter.

5. The semiconductor device handling apparatus according to claim 4, wherein
the second optical transmitter comprises a second incident portion that receives the third optical signal,
the first optical transmitter comprises a second emission portion that emits the second optical signal, and
the second incident portion and the second emission portion are disposed on the opposing surface such that the second incident portion and the second emission portion face the optical connection portion.

6. The semiconductor device handling apparatus according to claim 5, wherein the first optical transmitter comprises a first optical transmission path that transmits an optical signal between the first incident portion and the second emission portion, and
the second optical transmitter comprises a first optical transmission path that transmits an optical signal between the second incident portion and the first emission portion.

7. The semiconductor device handling apparatus according to claim 3, wherein the first optical transmitter further comprises:
a first incident portion that receives the first optical signal; and
a first lens, disposed between the tester transmitter and the first incident portion, that condenses the first optical signal at the first incident portion.

8. The semiconductor device handling apparatus according to claim 3, wherein the second optical transmitter further comprises:
a first emission portion that emits the fourth optical signal; and
a second lens, disposed between the tester transmitter and the first emission portion, that converts the fourth optical signal emitted from the first emission portion into a collimated light.

9. The semiconductor device handling apparatus according to claim 1, wherein the holder transmitter is separated from the tester transmitter when the holder contacts the terminal and the contact portion.

10. The semiconductor device handling apparatus according to claim 1, wherein the holder transmitter contacts the tester transmitter when the holder contacts the terminal and the contact portion.

11. The semiconductor device handling apparatus according to claim 1, wherein the holder comprises:
a main body including an opposing surface that opposes the second surface of the DUT; and
a suction holding mechanism that opens on the opposing surface and holds the DUT by suction.

12. The semiconductor device handling apparatus according to claim 1, wherein
the semiconductor device handling apparatus comprises a contact arm that holds the holder and moves the holder relative to the contact portion, and
the holder is detachably held at a tip of the contact arm.

13. A semiconductor device testing apparatus testing a device under test (DUT), comprising:
the semiconductor device handling apparatus according to claim 1; and
a tester that tests the DUT, wherein
the tester comprises:
a contact portion that inputs and outputs an electrical signal to and from the terminal; and
a tester transmitter that inputs and outputs a signal to and from the holder transmitter.

14. A semiconductor device testing apparatus testing a device under test (DUT), comprising:
the semiconductor device handling apparatus according to claim 7; and
a tester that tests the DUT, wherein
the tester comprises:
a contact portion that inputs and outputs an electrical signal to and from the terminal; and
a tester transmitter that inputs and outputs a signal to and from the holder transmitter,
the tester transmitter comprises:
a third emission portion that emits the first optical signal to the first incident portion; and
a fourth lens, disposed between the holder transmitter and the third emission portion, that converts the first optical signal emitted from the third emission portion into a collimated light.

15. A semiconductor device testing apparatus testing a device under test (DUT), comprising:
the semiconductor device handling apparatus according to claim 8; and
a tester that tests the DUT, wherein
the tester comprises:
a contact portion that inputs and outputs an electrical signal to and from the terminal; and
a tester transmitter that inputs and outputs a signal to and from the holder transmitter,
the tester transmitter comprises:
a third incident portion that receives the fourth optical signal from the first emission portion; and
a third lens, disposed between the holder transmitter and the third incident portion, that condenses the fourth optical signal at the third incident portion.

16. The semiconductor device testing apparatus according to claim 13, wherein the contact portion comprises a socket disposed on a test head, and the socket comprises:
a contactor contacting the terminal; and
the tester transmitter positioned outside of the contactor.
